(19) United States
(12) Patent Application Publication
(10) Pub. No.: US 2026/0236632 A1
(43) Pub. Date: Aug. 13, 2026

(54) RESIDENTIAL HVAC LOAD CALCULATIONS AND DESIGN

(71) Applicant: First Dimension Software, Haines City, FL (US)

(72) Inventors: Anthony Ray Amadio, Haines City, FL (US); Remi Clement Benjamin Taffin, Winter Garden, FL (US)

(21) Appl. No.: 19/532,689

(22) Filed: Feb. 6, 2026

Related U.S. Application Data
(60) Provisional application No. 63/755,941, filed on Feb. 7, 2025.

(51) Int. Cl. G06F 30/18

(52) U.S. Cl. CPC G06F 30/18

(57) ABSTRACT

The techniques described herein involve methods, systems, and computer program products for obtaining building information for generating an HVAC load calculation for a building. A system receives a construction plan document and apply a plurality of machine learning models to the construction plan document to obtain building information. The system generates a floorplan of the building based on the building information. The system uses the floorplan and building information to perform one or more HVAC load calculations.

### BACKGROUND

The construction approval process for buildings, including residential buildings, requires a determination of whether the HVAC design for the building meets load requirements set by various jurisdictions in which the construction is to occur. Determining whether an HVAC design meets load requirements involves a variety of calculations that are dependent on building information for the building, such as the type of walls, number of levels, direction that the building faces, type of insulation, materials used to construct the building, size of the building, the type of HVAC system to be installed, other building information, or some combination thereof.

### BRIEF DESCRIPTION OF THE SEVERAL VIEWS OF THE DRAWINGS

Non-limiting and non-exhaustive embodiments are described with reference to the following drawings. In the drawings, like reference numerals refer to like parts throughout the various figures. unless otherwise specified. For a better understanding, reference will be made to the following Detailed Description, which is to be read in association with the accompanying drawings:

FIG. 1 is a block diagram of an HVAC design system, according to one or more embodiments of the present disclosure.

FIG. 2 is a flowchart of a method for obtaining building information for generating an HVAC load calculation for a building, according to one or more embodiments of the present disclosure.

FIG. 3 is a first user interface for receiving second building information, according to various embodiments described herein.

FIG. 4 is a second user interface for receiving second building information, according to various embodiments described herein.

FIG. 5 is a third user interface for receiving second building information, according to various embodiments described herein.

FIG. 6 is a fourth user interface for receiving second building information, according to various embodiments described herein.

FIG. 7 is a fifth user interface for receiving second building information, according to various embodiments described herein.

FIG. 8 is a first chat box for receiving building information according to various embodiments described herein.

FIG. 9 is a second chat box for receiving building information according to various embodiments described herein.

FIG. 10 depicts a sixth user interface for generating a floorplan, according to some embodiments described herein.

FIG. 11 depicts a seventh user interface for generating a floorplan, according to some embodiments described herein.

FIG. 12 is a user interface element for defining the front facing direction of the building, according to various embodiments described herein.

FIG. 13 is a flowchart of a method for obtaining building information from a construction plan document, according to one or more embodiments of the present disclosure.

FIG. 14A is a eighth user interface for selecting a construction plan document, according to various embodiments described herein.

FIG. 14B is a ninth user interface for selecting a construction plan document, according to various embodiments described herein.

FIG. 15 is a tenth user interface for generating a floorplan based on a construction plan document, according to various embodiments described herein.

FIG. 16 is a eleventh user interface for generating a floorplan based on a construction plan document, according to various embodiments described herein.

FIG. 17 is a diagram illustrating an example computer system in which some described embodiments can be implemented.

### DETAILED DESCRIPTION

The construction approval process for buildings, including residential buildings, requires a determination of whether the HVAC design for the building meets load requirements set by various jurisdictions in which the construction is to occur. Determining whether an HVAC design meets load requirements involves a variety of calculations that are dependent on building information for the building, such as the type of walls, number of levels, direction that the building faces, type of insulation, materials used to construct the building, size of the building, the type of HVAC system to be installed, other building information, or some combination thereof. Reports are generated based on these calculations, the contents of which are used to determine whether construction plans for the building are approved. However, any error in the report, regardless of whether the error is minor and does not affect the HVAC load calculations, affects the HVAC load calculations, and may result in a non-approval of the construction plans.

Conventional HVAC design software include user interfaces for defining an HVAC load design for a building. However, conventional HVAC design software is unable to accurately account for the different materials on each level of the building. Furthermore, conventional HVAC design software is unable to receive a construction plan document and quickly and accurately extract information regarding the materials, design, floorplan, etc., of the building. Additionally, conventional HVAC design software is unable to alert a user that building information for performing selected load calculations has not been received until the load calculation is attempted and fails due to the missing information.

Accordingly, the inventors have conceived and reduced to practice systems and methods for HVAC load calculations and design (referred to herein as an “HVAC design system” or the “system”). The system receives input indicating building information and weather information for a building, and generates one or more reports indicating HVAC load calculations for the building based on the building information and weather information. In some embodiments, the system receives a construction plan document and extracts building information and generates a floorplan of the building based on the construction plan document. The systems and methods described herein may be used for residential HVAC load calculations and design, commercial HVAC load calculations and design, or some combination thereof.

By performing in some or all of the ways described herein, the system generates a representation of a building's HVAC system and generates load calculations for the HVAC system. Also, the facility improves the functioning of computer or other hardware, such as by reducing the dynamic display area, processing, storage, and/or data transmission resources needed to perform a certain task, thereby enabling the task to be permitted by less capable, capacious, and/or expensive hardware devices, and/or be performed with lesser latency, and/or preserving more of the conserved resources for use in performing other tasks. For example, conventional HVAC design software requires users to navigate through many disordered menus and to attempt to perform a load calculation before checking whether data used for the load calculation has been input into the software. These processes cause the HVAC design software to use additional processing cycles and memory in order to render all of the disordered menus and to attempt and fail to perform the load calculations before checking whether data for the load calculation has been input into the software. However, the system described herein is able to reduce the processing cycles and memory usage by determining whether building information for performing a selected load calculation has been received and requesting that information from the user, thereby preventing the failed attempt to perform the load calculation. The system described herein is also able to reduce processing cycles and memory usage by reducing the number of menus and interfaces necessary to load building information into HVAC design software by extracting building information directly from construction plan documents for the building.

Further, for at least some of the domains and scenarios discussed herein, the processes described herein as being performed automatically by a computing system cannot practically be performed in the human mind, for reasons that include that the starting data, intermediate state(s), and ending data are too voluminous and/or poorly organized for human access and processing, and/or are a form not perceivable and/or expressible by the human mind; the involved data manipulation operations and/or subprocesses are too complex, and/or too different from typical human mental operations; required response times are too short to be satisfied by human performance; etc.

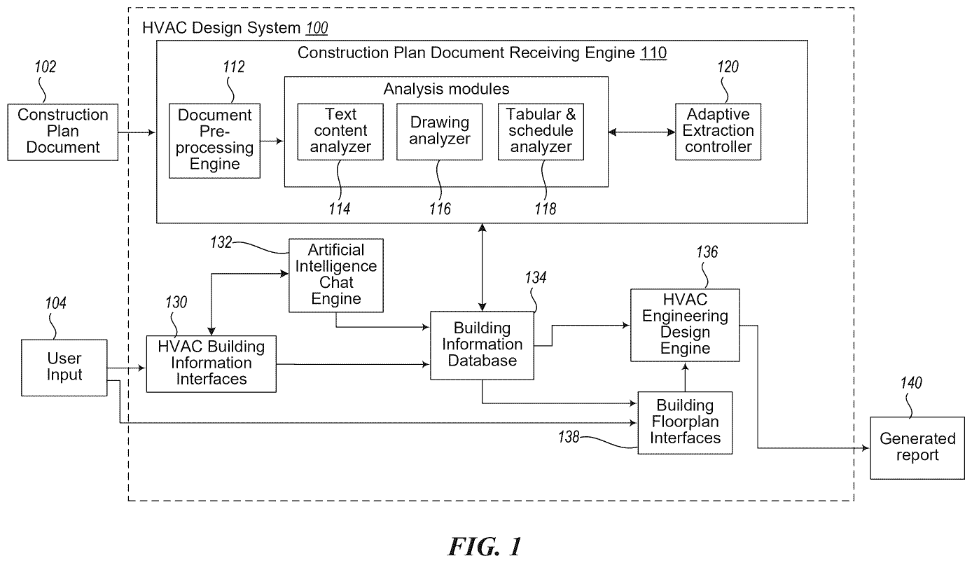

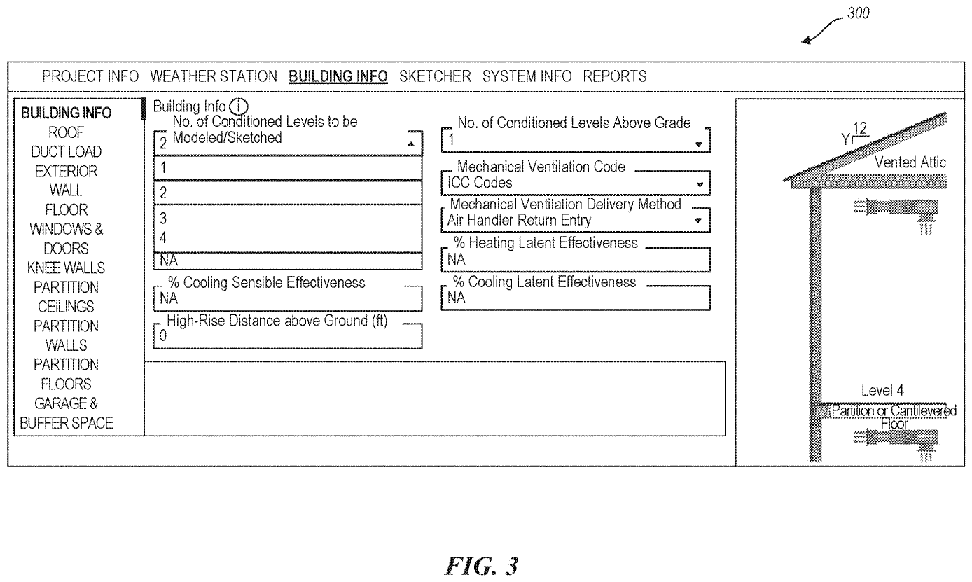

FIG. 1 is a block diagram of an HVAC design system 100, according to one or more embodiments of the present disclosure. The HVAC design system 100 (the “system 100”) includes a construction plan document receiving engine 110, one or more HVAC building information interfaces 130, one or more artificial intelligence chat engines 132, one or more building information databases 134, one or more HVAC engineering design engines 136, one or more and building floorplan interfaces 138. The system 100 may receive, as input, a construction plan document 102, user input 104, or a combination thereof, via one or more user interfaces or user interface elements, such as the user interfaces or user interface elements described below in connection with FIGS. 3-12 and 14-16. The system 100 may output a report 140 that indicates the predicted HVAC load of the building.

The construction plan document receiving engine 110 (the “document receiving engine 110”) includes a document pre-processing engine 112; one or more analysis modules such as the text content analyzer 114, drawing analyzer 116, and tabular and schedule analyzer 118; and an adaptive extraction controller 120. The document receiving engine 110 receives a construction plan document 102 and generates building information that is stored in the building information database 134.

The document pre-processing engine 112 identifies the content included in the construction plan document, the structure of the construction plan document, the relationships between content in the construction plan document, the text of the construction plan document, the images included in the construction plan document, etc. In some embodiments, the document pre-processing engine 112 includes a machine learning model trained to receive a construction plan document as input and to output an indication of one or more features of the document, such as the structure of the document, content of the document, relationships between content of the document, text data in the document, image data in the document, or a combination thereof.

The text content analyzer 114 identifies building information for a building based on the text of the construction plan document 102, such as notes, specifications, annotations, other text data included in the construction plan document 102, or a combination thereof. In some embodiments, the text content analyzer includes a machine learning model trained to receive text data from a construction plan document and output an indication of the building information identified in the text data.

The drawing analyzer 116 identifies building information for a building based on the images included in a construction plan document 102, such as floor plans, geometry, symbols, other image data included in the construction plan document 102, or a combination thereof. In some embodiments, the drawing analyzer includes a machine learning model trained to receive image data from a construction plan document and output an indication of the building information identified in the image data. In some embodiments, the drawing analyzer 116 outputs a representation of a floorplan of the building based on the image data. In some embodiments, the drawing analyzer 116 cleans the image, such as by converting the image to black and white, sharpening the image, or some combination thereof. In embodiments where the image is converted to black and white, the drawing analyzer 116 detects one or more aspects of the floor plans, geometry, symbols, etc., based on the portions of the image that are black. In some embodiments, the drawing analyzer 116 detects an aspect of a floor plan, geometry, symbol, etc., based on a determination that the intensity of the portion of the image exceeds a threshold amount. In some such embodiments, the training data for a machine learning model included in the drawing analyzer 116 includes one or more threshold amounts of intensity for detecting an aspect of a floor plan, geometry, symbol, etc.

The tabular and schedule analyzer 118 identifies building information for a building based on tables and schedules included in a construction plan document 102, such as equipment schedules, load tables, other tables or schedules included in the construction plan document 102, or a combination thereof. In some embodiments, the tabular and schedule analyzer 118 includes a machine learning model trained to receive table and schedule data from a construction plan document and output an indication of the building information identified in the table and schedule data.

In some embodiments, one or more of the artificial intelligence or machine learning models used by the analysis modules 114, 116, and 118 may be a large language model, such as GTP-40. In some embodiments, one or more of the analysis modules 114, 116, and 118 may output: one or more coordinates of one or more walls, such as coordinates of one or more corners of a wall; a shape of a room included in the architectural drawings; an indication of a type of room of one or more rooms of the building; an indication of a length of one or more walls; an indication of building information present in the architectural diagram; a scale of an architectural drawing; a placement of a door; a placement of a window; attributes of a door; attributes of a window; a front facing direction of a building; other data that may be included in a construction plan document for a building; or some combination thereof. In some embodiments, one or more of the artificial intelligence or machine learning models used by the analysis modules 114, 116, and 118 are trained based on data indicating one or more construction plan documents, information regarding the floorplan of a building indicated by the one or more construction plan documents, building information indicated by the one or more construction plan documents, or some combination thereof. In some embodiments, one or more of the artificial intelligence or machine learning models used by the analysis modules 114, 116, and 118 may be used to define one or more user interface fields associated building information based on the architectural drawings, such as materials used for the building, the size of the building, other building information, or some combination thereof.

In some embodiments, the functions of the analysis modules 114, 116, and 118, are performed by a single module, two modules, more than three modules, etc. In some embodiments, one or more functions of the analysis modules 114, 116, and 118, are performed by using one or more machine learning or artificial intelligence models, one or more multimodal models, or some combination thereof.

The adaptive extraction controller 120 identifies one or more analyses, confidence thresholds, or a combination thereof for the analysis modules 114, 116, and 118. The adaptive extraction controller 120 may identify one or more analyses, confidence thresholds, or a combination thereof, based on building information received from a construction plan document 102 and one or more selected HVAC load calculations. In some embodiments, the adaptive extraction controller 120 determines whether any additional building information is needed to perform one or more selected HVAC load calculations. In such embodiments, the adaptive extraction controller 120 identifies the analyses, confidence thresholds, or a combination thereof, based on the additional building information that is needed to perform the one or more selected HVAC calculations. For example, the adaptive extraction controller 120 may determine that additional information regarding a floorplan is required, and may adjust a confidence threshold for an image analysis module before applying the construction plan document 104 to the image analysis module to receive additional data regarding the floorplan.

In some embodiments, the output of one or more of the analysis modules 114, 116, and 118 is used as input for another of the analysis modules 114, 116, and 118. In some such embodiments, the adaptive extraction controller may select a portion of the output of at least one of the analysis modules 114, 116, and 118, to provide as input to at least one other of the analysis modules 114, 116, and 118, in order to refine the output of the analysis modules 114, 116, and 118.

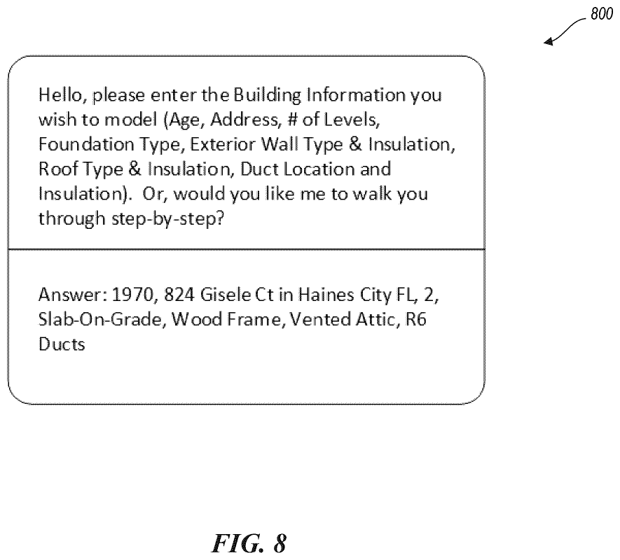

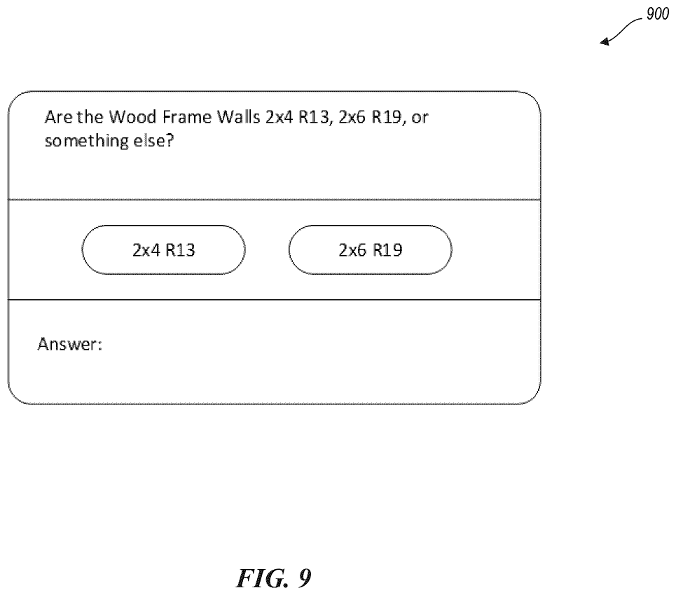

The artificial intelligence chat engine 132 includes one or more artificial intelligence or machine learning models for identifying building information that has not yet been obtained and generating one or more prompts to a user to provide the building information via user input. The artificial intelligence chat engine 132 may be used to obtain information via one or more chat boxes, such as the chat boxes 800 and 900 described below in connection with FIGS. 8 and 9, respectively.

The building information database 134 is a data store used to store building information received or generated for a building based on user input 104, a construction plan document 102, other sources of building information, or a combination thereof. In some embodiments, the building information database 134 includes a building information data structure that stores building information for each floor of the building represented by the building information data structure.

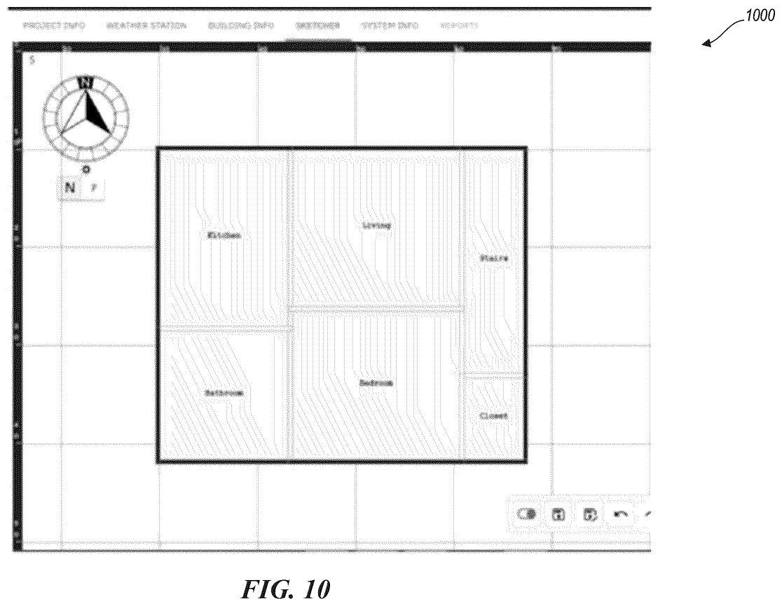

The building floorplan interfaces 138 are one or more user interfaces for generating or drawing a building floorplan, such as the user interfaces 1000, 1100, and 1600 described below in connection with FIGS. 10, 11, and 16 respectively.

The HVAC engineering design engine 136 generates a report based on the generated HVAC load for the building and the one or more construction codes or standards. In some embodiments, one or more attributes, or “properties,” of each material type indicated by the first building information, second building information, other building information, or some combination thereof, is applied to the one or more construction codes or standards to generate the HVAC load. In some embodiments, the system generates an indication of the efficiency of the HVAC system based on the generated HVAC load and properties of the HVAC system. In some such embodiments, the indication of the efficiency of the HVAC system is presented in the report as a percentage over or under the maximum load of the HVAC system.

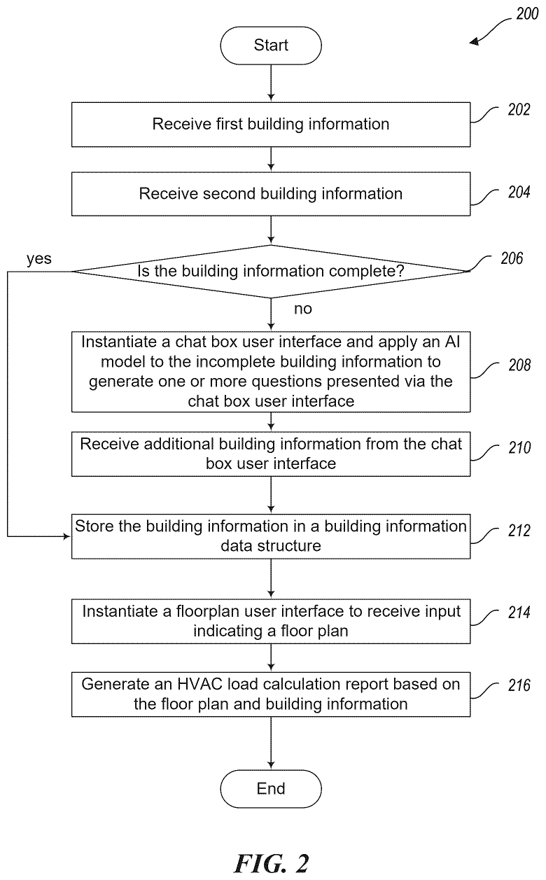

FIG. 2 is a flowchart of a method 200 for obtaining building information for generating an HVAC load calculation for a building, according to one or more embodiments of the present disclosure. Aspects of the method 200 may be performed by an HVAC design system 100, one or more components of the HVAC design system 100, or a combination thereof.

The method 200 begins, after a start block, at act 202, where first building information is received. In some embodiments, the first building information is received via one or more HVAC building information user interfaces, such as the HVAC building information user interfaces 130 described above in connection with FIG. 1. In some embodiments the first building information includes an indication of a location of a building, such as an address, latitude and longitude, etc.; an indication of a size of the building, such as in square feet, dimensions of exterior walls of the building, etc.; other information associated with a building; a weather station; or some combination thereof. In some embodiments, at least a portion of the first building information is extracted from a representation of the building, such as architectural drawings depicting the building. In some such embodiments, the method 1300 may be used to extract at least a portion of the first building information from a representation of the building. In some embodiments, the system identifies one or more weather stations based on the first portion of building information. In some embodiments, the system presents the one or more weather stations to a user via a user interface and receives a selection of the weather station via the user interface. In some embodiments, the system automatically selects the weather station, such as by selecting the nearest weather station to the building.

At act 204, second building information is received. In some embodiments, the second building is received via one or more HVAC building information user interfaces or user interface elements such as the HVAC building information user interfaces 130 described above in connection with FIG. 1 and the user interfaces 300-700, the chat boxes 800 and 900, and the user interface element 1200, described below in connection with FIGS. 3-12.

At act 206, it is determined whether the building information is complete. In some embodiments, the building information is determined to be complete if building information for one or more selected aspects of the building have been received. In some embodiments, the aspects of the building are selected based on one or more standards or codes for which load calculations are to be generated.

If it is determined the building information is complete, the method 200 proceeds to act 212, otherwise the method 200 proceeds to act 208.

At act 208, a chat box user interface is instantiated and an artificial intelligence or machine learning model is applied to the incomplete building information to generate one or more questions presented via the chat box user interface. In some embodiments, the chat box user interface may be similar to the chat boxes 800 and 900, described below with respect to FIGS. 8 and 9 respectively. In some embodiments, the chat box user interface is instantiated to receive user input in the form of text data, present options and receive a selection of a presented option, present or receive text data in other manner, or some combination thereof.

At act 210, additional building information is received from the chat box user interface.

At act 212, the first building information, second building information, and any additional building information is stored in a building information data structure. In some embodiments, the building information data structure stores building information for each level or floor of the building. In some embodiments, the building information data structure includes an indication of at least a portion of the first building information and second building information.

At act 214, a floorplan user interface is instantiated to receive input indicating a floor plan. In some embodiments, the floorplan user interface may be similar to the building floorplan interfaces 138, user interface 1000, or user interface 1100, described with respect to FIGS. 1, 10, and 11, respectively. In some embodiments, the floorplan user interfaces are configured to access the building information data structure to define attributes of walls, floors, doors, windows, ceilings, etc., according to the level of the building that is being defined via the floorplan user interface. For example, if the user of the user interface indicates that they are designing the floorplan of the first level (or “first floor”) of the building, the building information associated with the first level of the building is automatically used to define the attributes of the walls, floors, doors, windows, ceilings, etc., designed on the first level of the building.

In some embodiments, an image of a floorplan extracted from a construction plan document 102, such as by using a drawing analyzer 114, is overlayed onto the floorplan user interface. In such embodiments, the floorplan user interface may be configured to allow a user to draw the floorplan and define sections of the floorplan (e.g. windows, walls, floors, doors, ceilings, etc.) on top of the overlayed image of the floorplan. In some such embodiments, the image of the floorplan and input received by the user to draw and define sections of the floorplan may be used as training data for a machine learning model associated with the drawing analyzer 114.

At act 216, an HVAC load calculation report is generated based on the floor plan and the building information stored int eh building information data structure. In some embodiments, after receiving the first building information, second building information, and generating the floorplan, the system receives an indication of an HVAC system. In some embodiments, the system receives the indication of the HVAC system via a user interface, by identifying the HVAC system in architectural plans, such as by using one of the machine learning or artificial intelligence models described above in connection with FIG. 1, or some combination thereof.

In some embodiments, the HVAC engineering design engine may generate the HVAC load for the building by applying one or more construction codes or standards to the indication of the HVAC system, the first building information, second building information, generated the floorplan, or a combination thereof, to generate the HVAC load for the building. In some embodiments, an HVAC load report is generated based on the generated HVAC load for the building and the one or more construction codes or standards.

After act 216, the method 200 ends.

In some embodiments, the system receives the second building information via one or more user interfaces, such as the user interfaces depicted in FIGS. 3-7. The user interfaces depicted in FIGS. 3-7 may be used to receive building information related to the number of levels of a building, a roof of the building, one or more duct loads of the building, one or more exterior walls of the building, one or more floors of the building, one or more windows and doors of the building, one or more “knee walls” of the building, one or more partitioned ceilings of the building, one or more partitioned walls of the building, one or more partitioned floors of the building, one or garages or buffer space of the building, or some combination thereof. In some embodiments, the building information indicates different duct load information for each level a plurality of levels of the building. In some embodiments, the building information indicates different exterior wall information for each level a plurality of levels of the building.

FIG. 3 is a first user interface 300 for receiving second building information, according to various embodiments described herein. The first user interface 300 may include one or more user interface elements for receiving building information associated with a number of levels of the building to be modeled, a number of levels above grade, one or more standards or “codes” for which load calculations are to be generated, the effectiveness of a heating device, the effectiveness of a cooling device, a distance above ground, or other building information. In some embodiments, the one or more standards or codes are ventilation standards and codes. In some embodiments, the first user interface 300 includes a depiction of a cross-section of the building. The depiction of the cross-section of the building may indicate a thickness of walls; thickness of floors; thickness of roof; one or material types of a wall, floor, roof, or some combination thereof; an HVAC or other heating system, cooling system, etc.; the levels of the building; insulation used in one or more levels of the building; or some combination thereof. In some embodiments, the system may change or alter the depiction of the cross-section of the building based on the second building information, such as after a predetermined time period, as portions of the second portion of building information are received, etc. In some embodiments, the user interface 300 may be used as performing act 204.

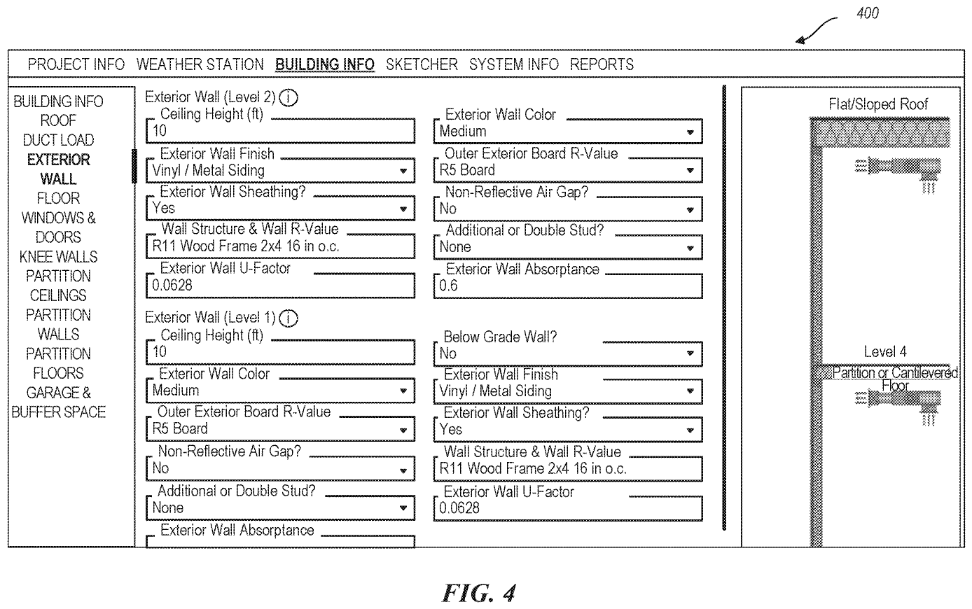

FIG. 4 is a second user interface 400 for receiving second building information, according to various embodiments described herein. The second user interface 400 may include user interface elements for receiving information associated with one or more exterior walls of one or more levels a building, such as a ceiling height; a wall color; a wall finish; one or more material types of a wall; an air gap; other information associated with an exterior wall; or some combination thereof. In some embodiments, the second user interface 400 receives information associated with exterior walls for each level of the building. In some embodiments, the second user interface 400 includes a cross-section of the building similar to the cross-section depicted in FIG. 3. In some embodiments, the user interface 400 may be used as performing act 204.

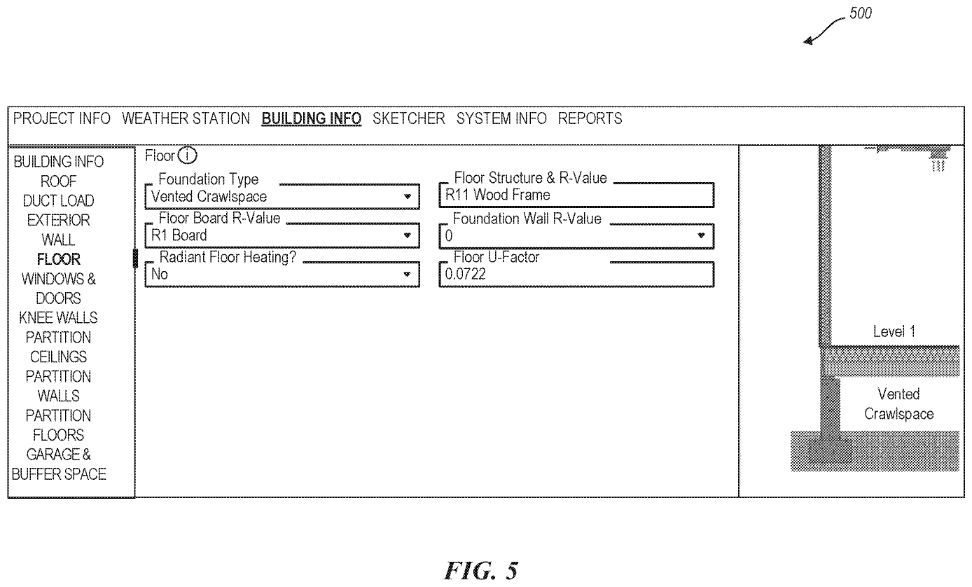

FIG. 5 is a third user interface 500 for receiving second building information, according to various embodiments described herein. The third user interface 500 may include user interface elements for receiving information related to the floor of one or more levels of the building, such as a material type of the floor, a foundation type of the floor (slab-on-grade, crawlspace, below grade, open/raised, etc.), whether the floor includes radiant heating, floor insulation, foundation insulation, other information associated with the floor of the building, or some combination thereof. In some embodiments, the third user interface 500 includes a cross-section of the building similar to the cross-section depicted in FIG. 3. In some embodiments, the user interface 500 may be used as performing act 204.

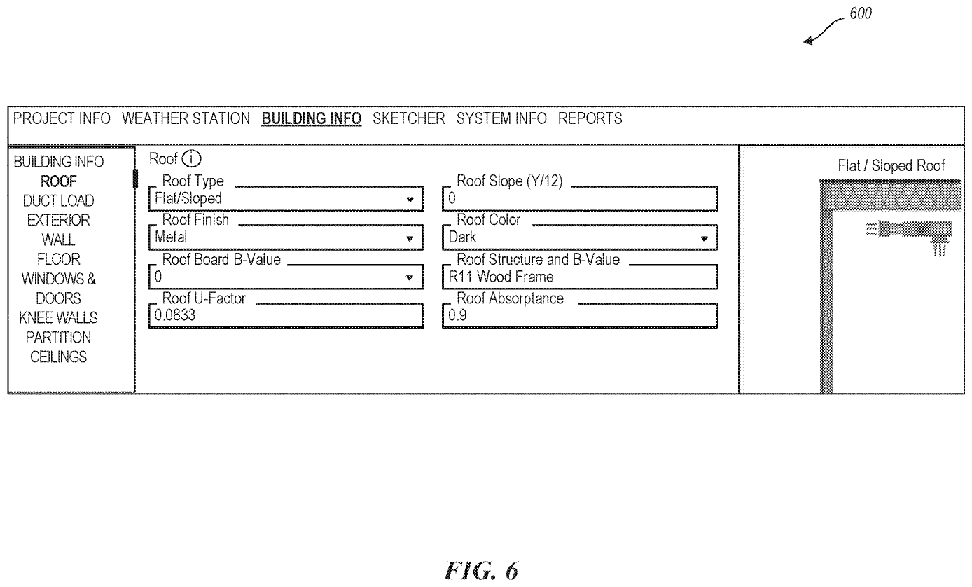

FIG. 6 is a fourth user interface for receiving second building information 600, according to various embodiments described herein. The fourth user interface 600 may include one or more user interface elements configured to receive information associated with a roof construction of a building, such as a roof type (attic, flat roof, etc.), a roof material (shingle, tile, metal, etc.), a roof finish, a roof slope, roof color, roof insulation, ceiling insulation, other information associated with a roof, or some combination thereof. In some embodiments, the fourth user interface 600 includes a cross-section of the building similar to the cross-section depicted in FIG. 3. In some embodiments, the user interface 600 may be used as performing act 204.

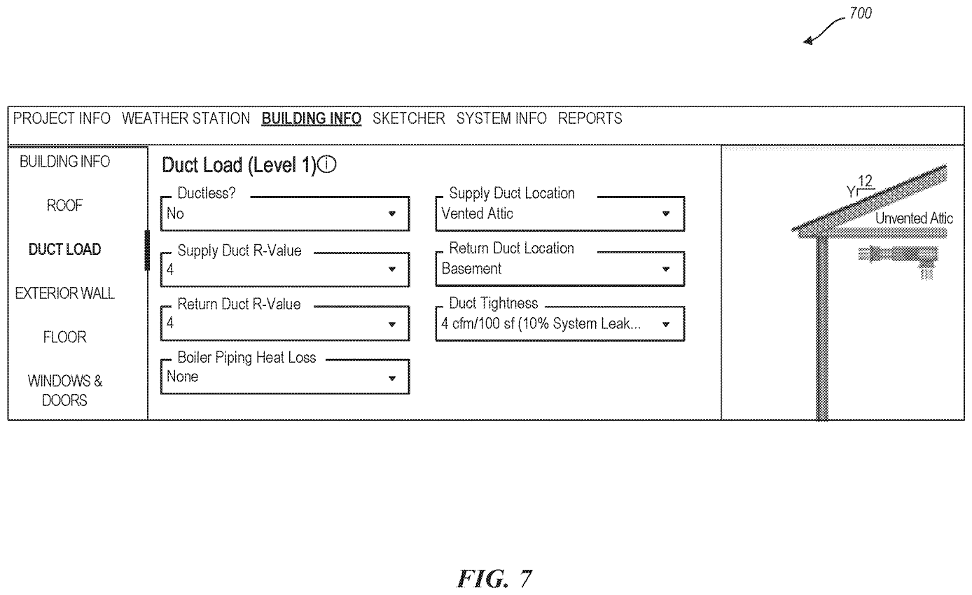

FIG. 7 is a fifth user interface 700 for receiving second building information, according to various embodiments described herein. The fifth user interface 700 may include one or more user interface elements configured to receive information associated with a duct load of one or more levels of a building, such as whether the building is ductless, the number of supply duct valves, a number of return duct valves, a return duct location, a supply duct location, a duct tightness, a boiler pipe heating loss, other information associated with a duct load, or some combination thereof. In some embodiments, the second user interface 400 receives information associated with a duct load for each level of the building. In some embodiments, the fifth user interface 700 includes a cross-section of the building similar to the cross-section depicted in FIG. 3. In some embodiments, the user interface 700 may be used as performing act 204.

FIG. 8 is a first chat box 800 for receiving building information according to various embodiments described herein. The first chat box 800 may be used to receive building information from the user as input, such as in the form of text, an uploaded file, etc. The system 100 may apply an artificial intelligence model, such as a natural language processing model, to the input received at the first chat box to extract building information from the input. In some embodiments, the artificial intelligence model is trained to extract building information from input based on building information for other buildings, HVAC protocols, standard construction terminology, or a combination thereof. In some embodiments, the artificial intelligence model outputs extracted building information. In some embodiments, the output of the artificial intelligence model includes data indicating second building information that was not received via the first chat box 800. In some embodiments, the artificial intelligence model is an artificial intelligence chat engine 132, described above in connection with FIG. 1. In some embodiments, the chat box 800 may be used as performing acts 208 and 210.

FIG. 9 is a second chat box 900 for receiving building information according to various embodiments described herein. The system 100 may determine that a portion of the first or second building information was not received as input, and may present the second chat box to a user in response to such a determination. In some embodiments, the artificial intelligence model described above in connection with FIG. 8, another artificial intelligence model, or some combination thereof, generates one or more prompts based on the determination that a portion of the building information was not received as input. In some such embodiments, the artificial intelligence model described above in connection with FIG. 8, another artificial intelligence model, or some combination thereof, generates one or more predicted answers to the prompt. The system 100 may display the one or more predicted answers to the prompt to the user via the second chat box 900. A user may select at least one of the one or more predicted answers to the prompt via the second chat box 900, may input their own answer to the prompt, or some combination thereof. The system may receive a portion of the building information based on the answer to the prompt presented to the user. In some embodiments, the chat box 900 may be used as performing acts 208 and 210.

By using the artificial intelligence model(s) and chat boxes 800 and 900, the system is able to receive building information without requiring the user to navigate one or more menus or user interfaces, or requiring the user to interact with user interface elements included in one or more user interfaces, such as the user interfaces described above in connection with FIGS. 3-7. The artificial intelligence model used in connection with FIG. 9 may be trained in a similar manner to the artificial intelligence model used in connection with FIG. 8. In some embodiments, the system 100 continues to use the first chat box 800, second chat box 900, or some combination thereof, to obtain building information until at least a subset of the building information used to perform one or more selected HVAC load calculations is received.

In some embodiments, a user may activate the first chat box 800, second chat box 900, or some combination thereof, by interacting with one or more user interface elements presented in one or more user interfaces, such as the user interfaces described above in connection with FIGS. 3-7 (not shown). In some embodiments, the system automatically activates the first chat box 800, second chat box 900, or some combination thereof, based on a determination that the at least a portion of the building information used to perform one or more selected HVAC load calculations has not been received as input.

In some embodiments, the first chat box 800, second chat box 900, or some combination thereof receives an indication that a user requests additional information. In such embodiments, one or more artificial intelligence models associated with the first chat box 800, second chat box 900, or some combination thereof, may output an answer to the request for additional information. In some such embodiments, the answer includes the information requested by the user. In some embodiments, the one or more artificial intelligence models associated with the first chat box 800, second chat box 900, or some combination thereof may be trained to output the additional information based on data describing one or more materials, one or more HVAC systems, one or more HVAC load calculations, one or more HVAC protocols, one or more construction codes or standards, one or more frequently asked questions and answers to such questions, other data associated with construction, or some combination thereof. In some embodiments, one or more artificial intelligence models associated with the first chat box 800, second chat box 900, or some combination thereof, are large language machine learning models, such as, for example, GTP-40.

In some embodiments, one or more artificial intelligence models associated with the first chat box 800, second chat box 900, or some combination thereof, predict building information that has not yet been defined based on building information that has been defined. In some such embodiments, the predicted building information is updated when additional building information is received, such as by applying the one or more artificial intelligence models to the additional building information and the building information that has been received.

FIG. 10 depicts a sixth user interface 1000 for generating a floorplan, according to some embodiments described herein. The sixth user interface 1000 includes one or more user interface elements that allow a user to draw a floorplan of a building. In some embodiments, interacting with the sixth user interface 1000, such as by clicking a point in the sixth user interface 1000 with a mouse and moving the mouse cursor before releasing the click, causes a wall to be generated. In some embodiments, interacting with the sixth user interface 1000 to generate a wall outside of an enclosed polygon generates an exterior wall. In some embodiments, interacting with the sixth user interface 1000 to generate a wall inside of an enclosed polygon generates an interior wall. In some embodiments, the sixth user interface 1000 includes user interface elements for labeling rooms, defining interior or exterior wall types, indicating a portion of a wall includes a window, indicating a portion of a roof includes a sky light, indicating a portion of a wall includes a door, indicating other aspects of a floorplan of a building, or some combination thereof. In some embodiments, the system 100 generates a three-dimensional model of a building based on a generated floorplan. In some embodiments, in the generated floorplan, the “top” of the floorplan is the back of the building, the “bottom” of the floorplan is the front of the building, the “left-side” of the floorplan is the left-side of the building, and the “right-side” of the floorplan is the right-side of the building. In some embodiments, the user interface 1000 may be used as performing act 214.

In some embodiments, the sixth user interface 1000 includes user interface elements for changing building construction information for a selected aspect of the building, such as an exterior wall, a window, a door, a floor, a knee wall, a partitioned ceiling, a partitioned wall, a partitioned floor, a garage or buffer space, a duct load, etc. In such embodiments, changing the building construction information for the selected aspect of the building includes changing one or more material types, dimensions, or other attributes of the selected aspect of the building.

In some embodiments, the sixth user interface 1000 includes one or more user interface elements for identifying one or more architectural drawings of the building. In some embodiments, the one or more architectural drawings may be in the form of a PDF, an image, another form of storing an architectural drawing as data, or some combination thereof. In some embodiments, at least a portion of the one or more architectural drawings are overlayed onto the sixth user interface 1000, such that a user is able to “trace” the portion of the one or more architectural drawings to draw the floorplan of the building.

In some embodiments, the system applies an artificial intelligence model to one or more architectural diagrams to obtain information regarding the floorplan of a building, first building information, second building information, other building information, or some combination thereof. In such embodiments, the system may automatically generate the floorplan of the building based on the output of the artificial intelligence model. In some such embodiments, the method 1300, user interfaces 1400, 1450, 1500, and 1600, or some combination thereof, may be used to automatically generate the floorplan of the building based on the output of the artificial intelligence model.

In some embodiments, the system determines a scale of a floorplan indicated by architectural drawings based on the architectural drawings received as input. In some such embodiments, the system determines a scale of the architectural drawings by detecting a scale included in the architectural drawings, such as by using one or more of the artificial intelligence models described above in connection with the analysis modules of the document receiving engine 110, described above in connection with FIG. 1. In some embodiments, the system determines one or more dimensions of one or more aspects of a floorplan, such as a length of a wall, length of a window, length of a door, etc., based on the determined scale. In some embodiments, the system determines a size of an architectural drawing based on a page size of the architectural drawing, pixel dimensions of an architectural drawing, other aspects of the architectural drawing, or some combination thereof. In some embodiments, the system determines one or more dimensions of one or more aspects of the floorplan based on the determined scale and determined size of the architectural drawing.

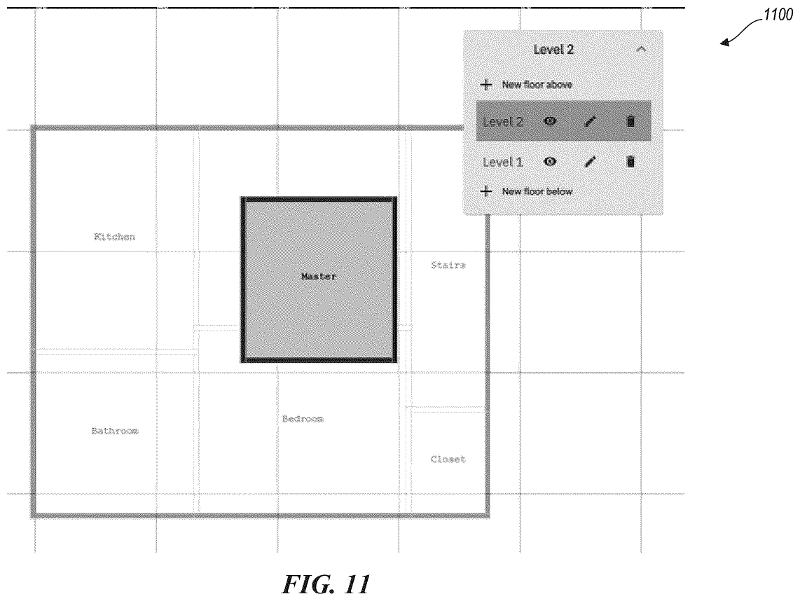

FIG. 11 depicts a seventh user interface 1100 for generating a floorplan, according to some embodiments described herein. The seventh user interface 1100 includes user interface elements to allow a user to re-arrange floors, or “levels,” of a floorplan of a building. In the seventh user interface, a user may select a level of the building, and may use user interface elements of the seventh user interface to define one or more aspects of the floorplan of the building, such as in a similar manner as described above in connection with FIG. 10. In some embodiments, the artificial intelligence model described above in connection with FIG. 10 generates floorplans for at least two levels of the building for which architectural diagrams are provided. In some embodiments, the user interface 1100 may be used as performing act 214.

In some embodiments, when a user activates a user interface element to select a level of the building, the system automatically defines exterior walls, duct loads, exterior floors, windows, doors, other aspects of the floorplan (including interior or exterior aspects of the floor plan), or some combination thereof, based on building information indicating a material type of the aspects of the floorplan for the selected level. In such embodiments, the building information may be stored in a building information data structure generated as part of performing the method 200 described above in connection with FIG. 2. For example, when a user selects the second level, the system 100 automatically defines walls drawn by the user to be walls that are made up of a material indicated by the building information data structure as material that is used for the second level. Continuing the example, when the user selects the first level, the system automatically defines walls drawn by the user to be walls that are made up of a material indicated by the building information data structure as material that is for the first level.

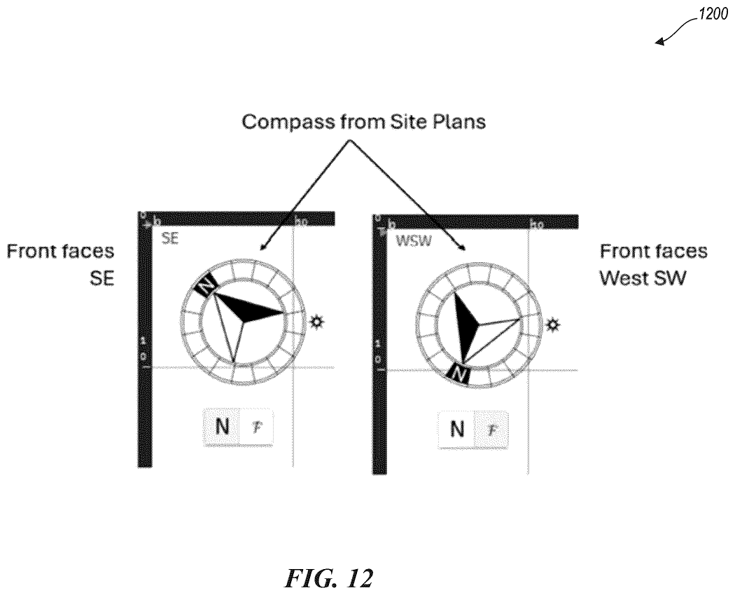

FIG. 12 is a user interface element 1200 for defining the front facing direction of the building, according to various embodiments described herein. The second building information may include the front facing direction of the building. Although the user interface element 1200 depicted in FIG. 12 shows sixteen cardinal directions that may be selected by a user, embodiments are not so limited, and the user interface element may include additional or fewer cardinal directions. In some embodiments, the user interface element receives the front facing direction of the building as a “degree” on a unit circle, where zero degrees is North, ninety degrees is East, one hundred and eighty degrees is south, etc. A user may select at least one of the cardinal directions to define the front facing direction of the building. In some embodiments, in response to the selection of a cardinal direction, the system automatically rotates the user interface element such that the cardinal direction selected by the user is to the right of the user interface element. In some embodiments, the system displays the cardinal direction selected by the user via the user interface element. In some embodiments, one or more of the analysis modules of the document receiving engine 110 are used to identify the front facing direction of the building based on a construction plan document.

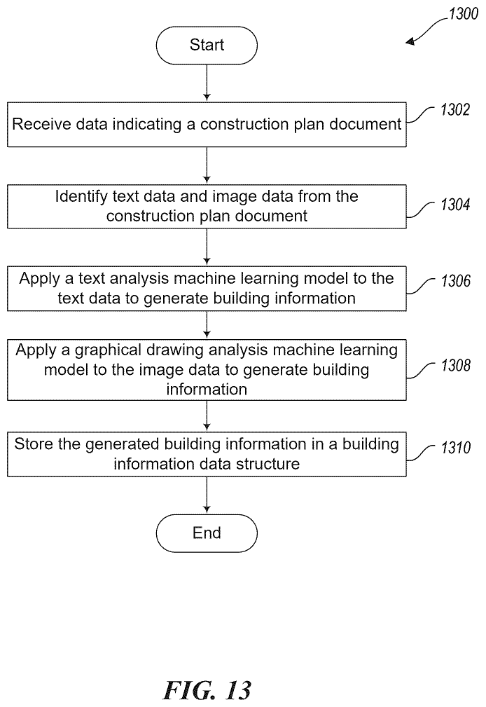

FIG. 13 is a flowchart of a method 1300 for obtaining building information from a construction plan document, according to one or more embodiments of the present disclosure. Aspects of the method 1300 may be performed by an HVAC design system 100, one or more components of the HVAC design system 100, or a combination thereof.

The method 1300 begins, after a start block, at act 1302, where data indicating a construction plan document is received. In some embodiments, the construction plan document is a PDF document. In some embodiments, the construction plan document includes one or more blueprints or other documents indicating a floorplan, wiring, HVAC system, materials, front-facing direction, other construction plan information, or some combination thereof.

At act 1304, text data and image data are identified in the construction plan document. In some embodiments, the text data includes data associated with the types of material used for the building; the front-facing direction of the building; the number of windows, doors, etc. in the floorplan; one or more dimensions of aspects of the building, such as windows, doors, ceilings, walls, etc.; a type of HVAC and other systems included in the building; other text data included in a construction plan document; or a combination thereof. In some embodiments, the image data includes data associated with a blueprint of the building included in the construction plan document, other image data included in construction plan document, or some combination thereof.

At act 1306, a text analysis machine learning model is applied to the text data to generate building information. In some embodiments, the text analysis machine learning model is a part of the text content analyzer 114, described above in connection with FIG. 1.

At act 1308, a graphical drawing analysis machine learning model is applied to the image data to generate building information. In some embodiments, the building information generated by the graphical drawing analysis machine learning model includes a floorplan of the building. In some such embodiments, the floorplan is editable by a user, such as by using one or more of the user interfaces 1000, 1100, 1600. In some embodiments, data indicating one or more edits to a generated floorplan is used as training data for training the graphical drawing analysis machine learning model. In some embodiments, the graphical drawing analysis machine learning model is included in the drawing analyzer 116, described above in connection with FIG. 1.

In some embodiments, the graphical drawing analysis machine learning model receives at least a portion of the output of the text analysis machine learning model along with the image data to generate the building information. In some such embodiments, at least a portion of the output of the graphical drawing analysis machine learning model is provided back to the text analysis machine learning model along with the text data to further refine the output of the text analysis machine learning model. In some embodiments, the graphical drawing analysis machine learning model receives the refined output of the text analysis machine learning model to refine the output of the graphical drawing analysis machine learning model.

By operating in this manner the outputs of both machine learning models are able to be refined to more accurately extract data from the construction plan document. Also, by operating in this manner, disadvantages of using a single model to extract both text and image data from the construction plan document are avoided-such as: being a larger model than two separate smaller models, and thus needing more processing cycles and memory to function; needing a larger set of training data to be able to train the model to perform both text extraction and image processing functions; and being less accurate than two specialized models that are able to use the other's output to refine their own output. Thus, by using multiple smaller models that feed each other their output in order to refine the ultimate output, the system is able to extract building information from a complex document (i.e. a document that includes images, text, and text overlayed onto images) more effectively, with fewer computing resources, and with less complex training data, than conventional methods of extracting information from a complex document.

In some embodiments, an adaptive extraction controller, such as the adaptive extraction controller 120, determines whether at least a portion of the output of the graphical drawing analysis machine learning model or the text analysis machine learning model is to be refined. In such embodiments, the adaptive extraction controller may apply the portion of the output of one of the machine learning models to the other machine learning model in order to refine the output.

In some embodiments, a tabular and schedule analyzer 118 is also used to generate building information. In such embodiments, tabular and schedule data may be identified in act 1304 and applied to the tabular and schedule analyzer 118. In some such embodiments, at least a portion of the output of the analyzer 118 may be refined based on the output of the graphical drawing analysis machine learning model, text analysis machine learning model, or a combination thereof. In some embodiments, the output of the graphical drawing analysis machine learning model, text analysis machine learning model, or a combination thereof, may be refined based on at least a portion of the output of the analyzer 118.

In some embodiments, acts 1306 and 1308 are performed by using a multimodal machine learning or artificial intelligence model. In such embodiments, the multimodal model is able to extract building information from text data, image data, schedule and table data, other data, or some combination thereof.

At act 1310, the generated building information is stored in a building information data structure. In some embodiments, act 1310 is performed in a similar manner to act 212, described above in connection with FIG. 2. In some embodiments, one or more of acts 214 and 216 are performed after act 1310.

In some embodiments, the building information stored in the building information data structure is used to generate a floorplan of the building. In some embodiments, the building information included in the building information data structure includes attributes of the walls, floors, ceilings, windows, doors, etc. (collectively “building aspects”), for each level of the building. In such embodiments, the system automatically applies the attributes corresponding to each level of the building to the floorplan (e.g. the attributes of the second level are automatically applied to the building aspects for the second level, the attributes of the first level are automatically applied to the building aspects for the first level, etc.). In some such embodiments, one or more of the analysis modules 114, 116, and 118, are configured to identify which attributes correspond to which level of the building based on the construction plan documents.

After act 1310, the method 1300 ends.

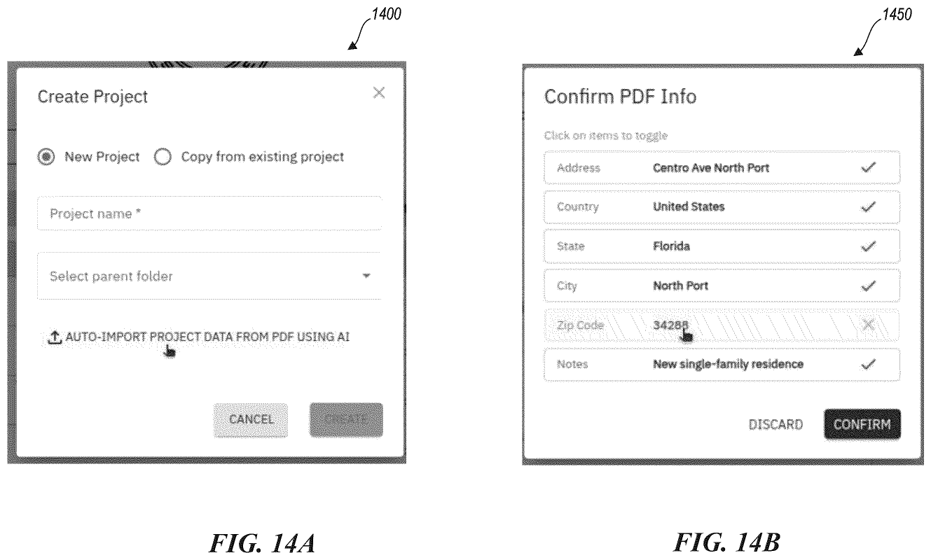

FIG. 14A is a eighth user interface 1400 for selecting a construction plan document, according to various embodiments described herein. The user interface 1400 may include one or more user interface elements for selecting and importing a construction plan document, such as the construction plan document 102 described above in connection with FIG. 1. In some embodiments, the eighth user interface 1400 may be used as performing act 1302.

FIG. 14B is a ninth user interface 1450 for selecting a construction plan document, according to various embodiments described herein. The user interface 1450 may include one or more user interface elements that display information extracted from the construction plan document. In some embodiments, the information is received via user input. In some embodiments, the information displayed by the user interface 1450 corresponds to the first building information described above with respect to act 202. In some embodiments, the information displayed by the user interface 1450 is extracted from the construction plan document by using the document pre-processing engine 112, described above in connection with FIG. 1. In some embodiments, the user interface 1450 may be used as performing act 1302.

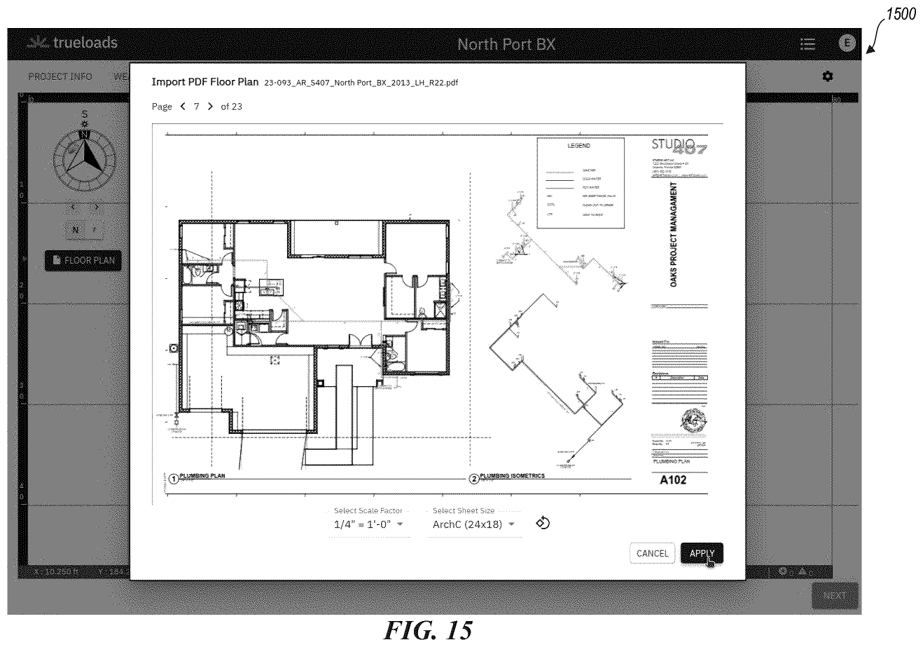

FIG. 15 is a tenth user interface 1500 for generating a floorplan based on a construction plan document, according to various embodiments described herein. The user interface 1500 may include user interface elements for presenting the construction plan document and allowing the selection of the scale factor and sheet size of the document. In some embodiments, the scale factor and sheet size of the document are automatically determined. In some embodiments, a document pre-processing engine, such as the document pre-processing engine 112, is configured to automatically identify the scale factor and sheet size of the document based on the construction plan document. In some embodiments, the system 100 uses the scale factor, sheet size of the document, building information extracted from the construction plan document, other information, or a combination thereof, to generate a floorplan of the building.

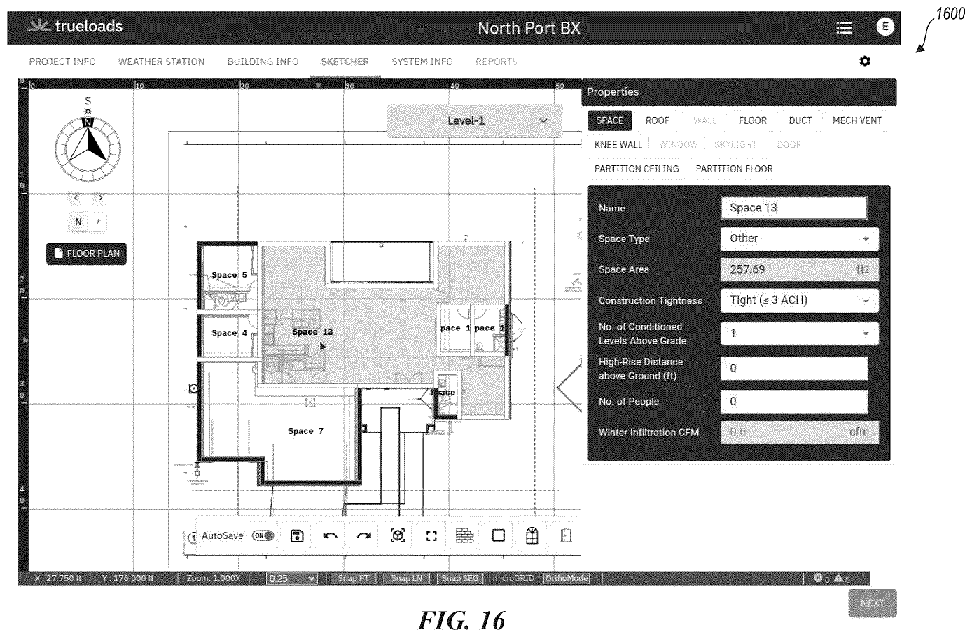

FIG. 16 is an eleventh user interface 1600 for generating a floorplan based on a construction plan document, according to various embodiments described herein. The user interface 1600 may include one or more user interface elements that display at least a portion of the building information and floorplan generated as part of performing acts 1306 and 1308. In some embodiments, the user interface 1600 includes user interface elements to allow the user to edit the floorplan and building information. In some embodiments, the system 100 detects when a user has changed a generated floorplan or building information. In such embodiments, the system 100 may store an indication of the change made by the user to be used as future training data for the machine learning models included in the analysis modules 114, 116, and 118, described above in connection with FIG. 1.

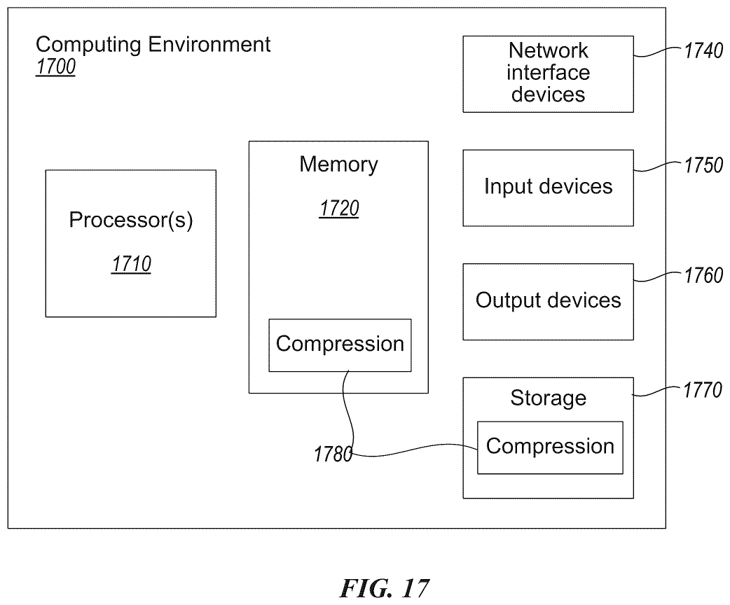

FIG. 17 illustrates a generalized example of a suitable computer system 1700 in which several of the described innovations may be implemented. The innovations described herein relate to HVAC design and load calculations. The computer system 1700 is an example of hardware on which the disclosed methods and systems can be implemented. The computer system 1700 is not intended to suggest any limitation as to scope of use or functionality, as the innovations may be implemented in diverse computer systems, including special-purpose computer systems.

With reference to FIG. 17, the computer system 1700 includes one or more processing cores 1710 which may include local processor memory 1718 of a central processing unit (“CPU”) or multiple CPUs. The processing core(s) 1710 are, for example, processing cores on a single chip, and execute computer-executable instructions. The number of processing core(s) 1710 depends on implementation and can be, for example, 4 or 8, or more. The local processor memory 1718 may be volatile memory (e.g., registers, cache, random access memory (“RAM”)), non-volatile memory (e.g., read-only memory (“ROM”), electrically erasable programmable ROM (“EEPROM”), flash memory), or some combination of the two, accessible by the respective processing core(s) 1710. Alternatively, the processing cores 1710 can be part of a system-on-a-chip (“SoC”), application-specific integrated circuit (“ASIC”), or other integrated circuit.

The local processor memory 1718 can store software 1780 implementing aspects of the present disclosure, for operations performed by the respective processing core(s) 1710, in the form of computer-executable instructions. In FIG. 17, the local memory 1718 is on-chip memory such as one or more caches, for which access operations, transfer operations, etc. with the processing core(s) 1710 are fast.

The computer system 1700 includes main memory 1720, which may be volatile memory (e.g., RAM), non-volatile memory (e.g., ROM, EEPROM, flash memory), or some combination of the two, accessible by the processing core(s) 1710. The main memory 1720 stores software 1780 implementing aspects of the present disclosure, in the form of computer-executable instructions. In FIG. 17, the main memory 1720 is off-chip memory, for which access operations, transfer operations, etc. with the processing cores 1710 are slower.

More generally, the term “processor” refers generically to any device that can process computer-executable instructions and may include a microprocessor, microcontroller, programmable logic device, digital signal processor, and/or other computational device. A processor may be a processing core of a CPU, other general-purpose unit, or GPU. A processor may also be a specific-purpose processor implemented using, for example, an ASIC or a field-programmable gate array (“FPGA”). A “processor system” is a set of one or more processors, which can be located together or distributed across a network.

The term “control logic” refers to a controller or, more generally, one or more processors, operable to process computer-executable instructions, determine outcomes, and generate outputs. Depending on implementation, control logic can be implemented by software executable on a CPU, by software controlling special-purpose hardware (e.g., a GPU or other graphics hardware), or by special-purpose hardware (e.g., in an ASIC).

The computer system 1700 includes one or more network interface devices 1740. The network interface device(s) 1740 enable communication over a network to another computing entity (e.g., server, other computer system). The network interface device(s) 1740 can support wired connections and/or wireless connections, for a wide-area network, local-area network, personal-area network, or other network. For example, the network interface device(s) can include one or more Wi-Fi® transceivers, an Ethernet® port, a cellular transceiver and/or another type of network interface device, along with associated drivers, software, etc. The network interface device(s) 1740 convey information such as computer-executable instructions, audio or video input or output, or other data in a modulated data signal over network connection(s). A modulated data signal is a signal that has one or more of its characteristics set or changed in such a manner as to encode information in the signal. By way of example, the network connections can use an electrical, optical, RF, or other carrier.

The computer system 1700 optionally includes one or more input devices 1750. The input devices 1750 could include any type of input devices including, but not limited to, a keyboard, a mouse, a touchscreen, a motion sensor/tracker input, a microphone, or a game controller.

The computer system 1700 optionally includes one or more output devices, such as a speaker, a display, etc.

The storage 1770 may be removable or non-removable, and includes magnetic media (such as magnetic disks, magnetic tapes or cassettes), optical disk media and/or any other media which can be used to store information, and which can be accessed within the computer system 1700. The storage 1770 stores instructions for the software 1780 implementing aspects of the present disclosure.

An interconnection mechanism (not shown) such as a bus, controller, or network interconnects the components of the computer system 1700. Typically, operating system software (not shown) provides an operating environment for other software executing in the computer system 1700, and coordinates activities of the components of the computer system 1700.

The computer system 1700 of FIG. 17 is a physical computer system. A virtual machine can include components organized as shown in FIG. 17.

The term “application” or “program” refers to software such as any user-mode instructions to provide functionality. The software of the application (or program) can further include instructions for an operating system and/or device drivers. The software can be stored in associated memory. The software may be, for example, firmware. While it is contemplated that an appropriately programmed general-purpose computer or computing device may be used to execute such software, it is also contemplated that hard-wired circuitry or custom hardware (e.g., an ASIC) may be used in place of, or in combination with, software instructions. Thus, examples described herein are not limited to any specific combination of hardware and software.

The term “computer-readable medium” refers to any medium that participates in providing data (e.g., instructions) that may be read by a processor and accessed within a computing environment. A computer-readable medium may take many forms, including non-volatile media and volatile media. Non-volatile media include, for example, optical or magnetic disks and other persistent memory. Volatile media include dynamic random-access memory (“DRAM”). Common forms of computer-readable media include, for example, a solid-state drive, a flash drive, a hard disk, any other magnetic medium, a CD-ROM, DVD, any other optical medium, RAM, programmable read-only memory (“PROM”), erasable programmable read-only memory (“EPROM”), a USB memory stick, any other memory chip or cartridge, or any other medium from which a computer can read. The term “non-transitory computer-readable media” specifically excludes transitory propagating signals, carrier waves, and wave forms or other intangible or transitory media that may nevertheless be readable by a computer. The term “carrier wave” may refer to an electromagnetic wave modulated in amplitude or frequency to convey a signal.

The innovations can be described in the general context of computer-executable instructions being executed in a computer system on a target real or virtual processor. The computer-executable instructions can include instructions executable on processing cores of a general-purpose processor to provide functionality described herein, instructions executable to control a GPU or special-purpose hardware to provide functionality described herein, instructions executable on processing cores of a GPU to provide functionality described herein, and/or instructions executable on processing cores of a special-purpose processor to provide functionality described herein. In some implementations, computer-executable instructions can be organized in program blocks. Generally, program blocks include routines, programs, libraries, objects, classes, components, data structures, etc. that perform particular tasks or implement particular abstract data types. The functionality of the program blocks may be combined or split between program blocks as desired in various embodiments. Computer-executable instructions for program blocks may be executed within a local or distributed computer system.

The terms “system” and “device” are used interchangeably herein. Unless the context clearly indicates otherwise, neither term implies any limitation on a type of computer system or device. In general, a computer system or device can be local or distributed, and a computer system can include any combination of special-purpose hardware and/or hardware with software implementing the functionality described herein.

Numerous examples are described in this disclosure and are presented for illustrative purposes only. The described examples are not, and are not intended to be, limiting in any sense. The presently disclosed innovations are widely applicable to numerous contexts, as is readily apparent from the disclosure. One of ordinary skill in the art will recognize that the disclosed innovations may be practiced with various modifications and alterations, such as structural, logical, software, and electrical modifications. Although particular features of the disclosed innovations may be described with reference to one or more particular examples, it should be understood that such features are not limited to usage in the one or more particular examples with reference to which they are described, unless expressly specified otherwise. The present disclosure is neither a literal description of all examples nor a listing of features of the present disclosure that must be present in all examples.

When an ordinal number (such as “first,” “second,” “third” and so on) is used as an adjective before a term, that ordinal number is used (unless expressly specified otherwise) merely to indicate a particular feature, such as to distinguish that particular feature from another feature that is described by the same term or by a similar term. The mere usage of the ordinal numbers “first,” “second,” “third,” and so on does not indicate any physical order or location, any ordering in time, or any ranking in importance, quality, or otherwise. In addition, the mere usage of ordinal numbers does not define a numerical limit to the features identified with the ordinal numbers.

When introducing elements, the articles “a,” “an,” “the,” and “said” are intended to mean that there are one or more of the elements. The terms “comprising,” including,” and “having” are intended to be inclusive and mean that there may be additional elements other than the listed elements.

When a single device, component, block, or structure is described, multiple devices, components, blocks, or structures (whether or not they cooperate) may instead be used in place of the single device, component, block, or structure. Functionality that is described as being possessed by a single device may instead be possessed by multiple devices, whether or not they cooperate. Similarly, where multiple devices, components, blocks, or structures are described herein, whether or not they cooperate, a single device, component, block, or structure may instead be used in place of the multiple devices, components, blocks, or structures. Functionality that is described as being possessed by multiple devices may instead be possessed by a single device. In general, a computer system or device can be local or distributed, and a computer system can include any combination of special-purpose hardware and/or hardware with software implementing the functionality described herein.

The respective techniques and tools described herein may be utilized independently and separately from other techniques and tools described herein.

Device, components, blocks, or structures that are in communication with each other need not be in continuous communication with each other, unless expressly specified otherwise. On the contrary, such devices, components, blocks, or structures need only transmit to each other as necessary or desirable, and they may actually refrain from exchanging data most of the time. For example, a device in communication with another device via the Internet might not transmit data to the other device for weeks at a time. In addition, devices, components, blocks, or structures that are in communication with each other may communicate directly or indirectly through one or more intermediaries.

As used herein, the term “send” denotes any way of conveying information from one device, component, block, or structure to another device, component, block, or structure. The term “receive” denotes any way of getting information at one device, component, block, or structure from another device, component, block, or structure. The devices, components, blocks, or structures can be part of the same computer system or different computer systems. Information can be passed by value (e.g., as a parameter of a message or function call) or passed by reference (e.g., in a buffer). Depending on context, information can be communicated directly or be conveyed through one or more intermediate devices, components, blocks, or structures. As used herein, the term “connected” denotes an operable communication link between devices, components, blocks, or structures, which can be part of the same computer system or different computer systems. The operable communication link can be a wired or wireless network connection, which can be direct or pass through one or more intermediaries (e.g., of a network).

As used herein, the term “set,” when used as a noun to indicate a group of elements, indicates a non-empty group, unless context clearly indicates otherwise. That is, the “set” has one or more elements, unless context clearly indicates otherwise.

As used herein, the term “based on” or “based at least in part on” indicates a dependence. A value or output X that is “based on” (or “based at least in part on”) a value or input Y depends on Y but can also depend on additional information or factors. Y can be directly or indirectly used when determining, assigning, generating, calculating, or creating X “based on” (or “based at least in part on”) Y. Thus, for example, the language determining or assigning X “based on” Y can indicate determining or assigning X using Y.

A description of an example with several features does not imply that all or even any of such features are required. On the contrary, a variety of optional features are described to illustrate the wide variety of possible examples of the innovations described herein. Unless otherwise specified explicitly, no feature is essential or required.

Further, although process steps and stages may be described in a sequential order, such processes may be configured to work in different orders. Description of a specific sequence or order does not necessarily indicate a requirement that the steps or stages be performed in that order. Steps or stages may be performed in any order practical. Further, some steps or stages may be performed simultaneously despite being described or implied as occurring non-simultaneously.

Description of a process as including multiple steps or stages does not imply that all, or even any, of the steps or stages are essential or required. Various other examples may omit some or all of the described steps or stages. Unless otherwise specified explicitly, no step or stage is essential or required. Similarly, although a product may be described as including multiple aspects, qualities, or characteristics, that does not mean that all of them are essential or required. Various other examples may omit some or all of the aspects, qualities, or characteristics.

An enumerated list of items does not imply that any or all of the items are mutually exclusive, unless expressly specified otherwise. Likewise, an enumerated list of items does not imply that any or all of the items are comprehensive of any category, unless expressly specified otherwise.

For the sake of presentation, the detailed description uses terms like “determine” and “select” to describe computer operations in a computer system. These terms denote operations performed by one or more processors or other components in the computer system, and these terms should not be confused with acts performed by a human being. The actual computer operations corresponding to these terms vary depending on implementation.

In the examples described herein, identical reference numbers in different figures. indicate an identical component, block, or operation. More generally, various alternatives to the examples described herein are possible. For example, some of the methods described herein can be altered by changing the ordering of the method acts described, by splitting, repeating, or omitting certain method acts, etc. The various aspects of the disclosed technology can be used in combination or separately. Some of the innovations described herein address one or more of the problems noted in the background. Typically, a given technique or tool does not solve all such problems. It is to be understood that other examples may be utilized and that structural, logical, software, hardware, and electrical changes may be made without departing from the scope of the disclosure.

In view of the many possible embodiments to which the principles of the present disclosure may be applied, it should be recognized that the illustrated embodiments are only preferred examples and should not be taken as limiting the scope. Rather, the scope of the present disclosure is defined by the following claims.

1. A system comprising:
at least one processor; and
at least one memory storing processor-executable instructions, the instructions, when executed by the at least one processor, cause the at least one processor to:
receive input indicating building information via one or more user interfaces;
apply one or more machine learning models to the received building information to obtain additional building information;
generate a floorplan of the building based on the building information and the additional building information;
present the generated floorplan of the building via a floorplan user interface; and
generate an HVAC load calculation based on the generated floorplan, the building information, and the additional building information.

2. The system of claim 1, wherein the at least one processor is further caused to:
identify one or more levels of the building based on the building information and additional building information; and
store the building information and additional building information in a building information data structure that associates one or more portions of the building information and one or more portions of the additional building information with each of the one or more levels of the building.

3. The system of claim 1, wherein the input includes an indication of a construction plan document, and wherein, to apply the one or more machine learning models to the received building information, the at least one processor is further caused to:
apply the one or more machine learning models to the construction plan document to extract at least a portion of the additional building information from the construction plan document.

4. The system of claim 1, wherein the at least one processor is further caused to:
receive user input via the floorplan user interface; and
change the generated floorplan based on the user input received via the floorplan user interface.

5. The system of claim 4, wherein the at least one processor is further caused to:
generate data indicating one or more changes to the generated floorplan indicated by the user input received via the floorplan user interface; and
designate the data indicating one or more changes to the generated floorplan as additional training data for at least one of the one or more machine learning models.

6. The system of claim 4, wherein the at least one processor is further caused to:
determine a level of the building associated with the user input received via the floorplan user interface;
identify a portion of the building information and additional building information that corresponds to the level of the building associated with the user input;
update a building information data structure based on the identified portion of the building information and additional building information, the level of the building associated with the user input, and the change to the generated floorplan.

7. The system of claim 1, wherein the at least one processor is further caused to:
receive a selection of a type of HVAC load calculation;
apply one or more machine learning models to the received building information and the selected type of HVAC load calculation to obtain additional building information.

8. The system of claim 7, wherein at least one machine learning model of the one or more machine learning models is associated with a chat box, and wherein the at least one processor is further caused to:
apply the at least one machine learning model to the received building information and the selected type of HVAC load calculation to generate a prompt for additional building information, the at least one machine learning model being trained to identify whether additional building information is required to perform the HVAC load calculation and to output a prompt for the additional building information;
display the prompt for additional building information via the chat box; and
receive user input regarding the additional building information via the chat box.

9. The system of claim 7, wherein at least one machine learning model of the one or more machine learning models is used to extract building information from a construction plan document, and wherein the at least one processor is further caused to:
determine whether the received building information and additional building information are sufficient to perform the selected type of HVAC load calculation;
based on a determination that the received building information and additional building information are not sufficient to perform the selected type of HVAC load calculation:
identify a type of building information required to perform the selected type of HVAC load calculation;
adjust one or more confidence thresholds of the at least one machine learning model based on the identified type of building information; and
apply the received building information and additional building information to the at least one machine learning model to obtain further additional building information.

10. One or more instances of non-transitory computer-readable medium storing instructions that, when executed by at least one processor, cause the at least one processor to:
receive input indicating building information via one or more user interfaces;
apply one or more machine learning models to the received building information to obtain additional building information;
generate a floorplan of the building based on the building information and the additional building information;
present the generated floorplan of the building via a floorplan user interface; and
generate an HVAC load calculation based on the generated floorplan, the building information, and the additional building information.

11. The one or more instances of non-transitory computer-readable medium of claim 10, wherein the at least one processor is further caused to:
identify one or more levels of the building based on the building information and additional building information; and
store the building information and additional building information in a building information data structure that associates one or more portions of the building information and one or more portions of the additional building information with each of the one or more levels of the building.

12. The one or more instances of non-transitory computer-readable medium of claim 10, wherein the input includes an indication of a construction plan document, and wherein, to apply the one or more machine learning models to the received building information, the at least one processor is further caused to:
apply the one or more machine learning models to the construction plan document to extract at least a portion of the additional building information from the construction plan document.

13. The one or more instances of non-transitory computer-readable medium of claim 10, wherein the at least one processor is further caused to:
receive user input via the floorplan user interface; and
change the generated floorplan based on the user input received via the floorplan user interface.

14. The one or more instances of non-transitory computer-readable medium of claim 10, wherein the at least one processor is further caused to:
receive a selection of a type of HVAC load calculation;
apply one or more machine learning models to the received building information and the selected type of HVAC load calculation to obtain additional building information.

15. A method comprising:
receiving input indicating building information via one or more user interfaces;
applying one or more machine learning models to the received building information to obtain additional building information;
generating a floorplan of the building based on the building information and the additional building information;
presenting the generated floorplan of the building via a floorplan user interface; and
generating an HVAC load calculation based on the generated floorplan, the building information, and the additional building information.

16. The method of claim 15, further comprising:
identifying one or more levels of the building based on the building information and additional building information; and
storing the building information and additional building information in a building information data structure that associates one or more portions of the building information and one or more portions of the additional building information with each of the one or more levels of the building.

17. The method of claim 15, wherein the input includes an indication of a construction plan document, and wherein, applying the one or more machine learning models to the received building information comprises:
applying the one or more machine learning models to the construction plan document to extract at least a portion of the additional building information from the construction plan document.

18. The method of claim 15, further comprising:
receiving user input via the floorplan user interface; and
changing the generated floorplan based on the user input received via the floorplan user interface.

19. The method of claim 15, further comprising:
receiving a selection of a type of HVAC load calculation;
applying one or more machine learning models to the received building information and the selected type of HVAC load calculation to obtain additional building information.

20. The method of claim 19, wherein at least one machine learning model of the one or more machine learning models is used to extract building information from a construction plan document, and wherein the method further comprises:
determining whether the received building information and additional building information are sufficient to perform the selected type of HVAC load calculation;
based on a determination that the received building information and additional building information are not sufficient to perform the selected type of HVAC load calculation:
identifying a type of building information required to perform the selected type of HVAC load calculation;
adjusting one or more confidence thresholds of the at least one machine learning model based on the identified type of building information; and
applying the received building information and additional building information to the at least one machine learning model to obtain further additional building information.
